(19) United States
(12) Patent Application Publication
(10) Pub. No.: US 2024/0412989 A1
(43) Pub. Date: Dec. 12, 2024

(54) THERMAL PROCESSING APPARATUS, THERMAL PROCESSING METHOD, AND SUBSTRATE TREATMENT EQUIPMENT

(71) Applicant: SEMES CO., LTD., Cheonan-si (KR)

(72) Inventors: Young Eun JEON, Cheonan-si (KR); Jong Won PARK, Cheonan-si (KR); Sung Min CHOI, Cheonan-si (KR); Woo Nam CHOI, Cheonan-si (KR); Kun Hee KO, Cheonan-si (KR); Yu Jung PARK, Cheonan-si (KR); Jung Min SIM, Cheonan-si (KR)

(73) Assignee: SEMES CO., LTD., Cheonan-si (KR)

(21) Appl. No.: 18/737,916

(22) Filed: Jun. 7, 2024

(30) Foreign Application Priority Data
Jun. 9, 2023 (KR) 10-2023-0074475

(51) Int. Cl. H01L 21/67; H01J 37/32; H01L 21/324; H01L 21/687

(52) U.S. Cl. CPC H01L 21/67109; H01J 37/32568; H01J 37/32724; H01L 21/68742; H01L 21/6875; H01L 21/68757; H01J 2237/2001; H01J 2237/20235; H01L 21/324

(57) ABSTRACT

Proposed are thermal processing apparatus, thermal processing method, and substrate treatment equipment, in which particle generation and damage to a substrate in the cooling process of the substrate can be prevented. The thermal processing apparatus includes a chamber having a processing zone therein, a plurality of chuck pins configured to support a substrate and move up or down individually, a heater configured to provide heat energy to the processing zone, a fluid supply port configured to supply a fluid to the processing zone, a fluid discharge port configured to discharge the fluid remaining in the processing zone to the outside, and a controller configured to control a treatment process of the substrate.

### CROSS REFERENCE TO RELATED APPLICATION

The present application claims priority to Korean Patent Application No. 10-2023-0074475, filed Jun. 9, 2023, the entire contents of which are incorporated by reference herein for all purposes.

### BACKGROUND OF THE INVENTION

### Field of the Invention

The present disclosure relates to a thermal processing apparatus, a thermal processing method, and substrate treatment equipment.

### Description of the Related Art

A semiconductor manufacturing process is a process for manufacturing a semiconductor device on a substrate (e.g., wafer) and includes, for example, exposure, deposition, etching, ion implantation, and cleaning, etc. In order to perform each manufacturing process, semiconductor manufacturing equipment that perform each process are provided in the clean room of a semiconductor manufacturing plant, and a thermal processing is performed on a substrate provided to each of the semiconductor manufacturing equipment.

In a semiconductor manufacturing process, thermal processing for modifying surface properties may be performed after treatment (e.g., etching) on a substrate. When thermal processing is performed on the substrate, the substrate is required to be cooled below a predetermined temperature for subsequent treatment. In order to cool the substrate, a process of supplying a cooling fluid to the substrate may be performed. When the entire area of the substrate is not cooled evenly, particles may be generated and the substrate may be damaged.

### SUMMARY OF THE INVENTION

Accordingly, the present disclosure has been made keeping in mind the above problems occurring in the related art, and the present disclosure is intended to propose a thermal processing apparatus, a thermal processing method, and substrate treatment equipment, in which particle generation and damage to a substrate in the cooling process of the substrate can be prevented.

In order to achieve the objectives of the present disclosure, according to an embodiment of the present disclosure, there is provided a thermal processing apparatus including: a chamber having a processing zone therein; a plurality of chuck pins configured to support a substrate and move up or down individually; a heater configured to provide heat energy to the processing zone; a fluid supply port configured to supply a fluid to the processing zone; a fluid discharge port configured to discharge the fluid remaining in the processing zone to the outside; and a controller configured to control a treatment process of the substrate. The controller heats the substrate by using the heater, controls a height of each of the chuck pins so that the substrate is maintained to be inclined, and supplies a cooling fluid through the fluid supply port to the inclined substrate.

According to the embodiment of the present disclosure, the chuck pin may include three chuck pins, and the three chuck pins may be arranged at equal intervals from each other.

According to the embodiment of the present disclosure, the chuck pin may be made of quartz.

According to the embodiment of the present disclosure, the chuck pin may include: a body part; an inner support part located on an inner side of an upper surface of the body part and configured to support a back surface of the substrate; and an outer support part located on an outer side of the upper surface of the body part and configured to support an edge side surface of the substrate.

According to the embodiment of the present disclosure, the inner support part may have a triangular pyramid shape having a width decreasing gradually upward.

According to the embodiment of the present disclosure, the outer support part may have a side wall which is flat in a vertical direction and a head extending from the side wall and having a width decreasing gradually upward.

According to the embodiment of the present disclosure, the controller may lower a chuck pin closest to the fluid supply port among the plurality of chuck pins.

According to the embodiment of the present disclosure, the controller may identify a position of a notch part of the substrate, and lower a chuck pin in non-contact with the notch part of the substrate and closest to the fluid supply port among the plurality of chuck pins.

According to the embodiment of the present disclosure, the controller may raise a chuck pin closest to the fluid discharge port among the plurality of chuck pins.

According to the embodiment of the present disclosure, the controller may identify the position of a notch part of the substrate, and raise the chuck pin in non-contact with the notch part of the substrate and closest to the fluid discharge port among the plurality of chuck pins.

According to the embodiment of the present disclosure, the thermal processing apparatus may further include a cooling plate provided on a lower part of the chamber, and having a through hole through the chuck pin passes and a cooling flow path in which a coolant flows.

According to the embodiment of the present disclosure, the fluid supply port may be located on an upper part of the chamber.

According to the embodiment of the present disclosure, the fluid discharge port may be located on a lower part of the chamber on an opposite side of the fluid supply port.

According to the present disclosure, there is a thermal processing method performed by the thermal processing apparatus, the method including: heating the substrate by using the heater; and cooling the substrate when the heating of the substrate is completed. The cooling of the substrate includes: controlling a height of each of the chuck pins so that the substrate is maintained to be inclined; and supplying a cooling fluid through the fluid supply port to the inclined substrate.

According to the present disclosure, there is provided a substrate treatment equipment including: a load port configured to accommodate a container in which a plurality of substrates is received; a processing module configured to perform process treatment on each of the substrates; and a transfer module configured to temporarily store the substrate withdrawn from the container and to transfer the substrate to the processing module. The processing module includes: a chamber having a processing zone therein; a plurality of chuck pins configured to support the substrate and move up or down individually; an upper electrode to which power is applied to generate plasma in the processing zone; a chuck located at a lower part of the processing zone, with the chuck having a lower electrode for generating the plasma and a cooling plate in which a cooling flow path in which a coolant is capable of flowing is formed; a heater configured to provide heat energy to the processing zone; a fluid supply port configured to supply a fluid to the processing zone; a fluid discharge port configured to discharge the fluid remaining in the processing zone to the outside; and a controller configured to control the process treatment of the substrate.

According to the present disclosure, after thermal processing, a cooling fluid is allowed to flow evenly along the entire area of the slanting substrate, thereby preventing particle generation and damage to the substrate.

### BRIEF DESCRIPTION OF THE DRAWINGS

The above and other objectives, features, and other advantages of the present disclosure will be more clearly understood from the following detailed description when taken in conjunction with the accompanying drawings, in which:

FIG. 1 schematically illustrates the structure of a thermal processing apparatus according to the present disclosure;

FIG. 2 illustrates chuck pins viewed from the upper side;

FIG. 3 illustrates the configuration of a chuck pin from the side;

FIG. 4 is a flowchart illustrating a thermal processing process according to the present disclosure;

FIG. 5 is a flowchart illustrating a cooling process according to the present disclosure a substrate;

FIGS. 6 and 7 illustrate the process of controlling the height of the chuck pin in the cooling process of the substrate according to the present disclosure;

FIG. 8 illustrates the shape of a cooling plate according to the present disclosure;

FIG. 9 illustrates the layout of substrate treatment equipment according to the present disclosure;

FIG. 10 illustrates the structure of a processing module in the substrate treatment equipment according to the present disclosure; and

FIG. 11 is a flowchart illustrating the treatment process of the substrate according to the present disclosure.

### DETAILED DESCRIPTION OF THE INVENTION

Hereinafter, with reference to the attached drawings, embodiments of the present disclosure will be described in detail so that those skilled in the art can easily perform them. The present disclosure may be implemented in various different forms and is not limited to the embodiments described herein.

In order to clearly explain the present disclosure, parts unrelated to the description are omitted, and identical or similar elements are given the same reference numerals throughout the specification.

In addition, in various embodiments, components having the same configurations will be described only in a representative embodiment by using the same reference numerals, and in other embodiments, only configurations that are different from that of the representative embodiment will be described.

Throughout the specification, when a part is said to be “connected (or combined)” with another part, this includes not only a case in which the part is “directly connected (or combined)” with another member, but also a case in which the part is “indirectly connected (or combined)” with another member with still another member placed therebetween. Also includes “combined” ones. In addition, when a part is described to “include” a certain component, this means that the part may further include other components rather than excluding the other components, unless specifically stated to the contrary.

Unless otherwise defined, all terms used herein, including technical or scientific terms, have the same meanings as commonly understood by those skilled in the art to which the present disclosure pertains. Terms defined in commonly used dictionaries should be interpreted as having meanings consistent with meanings in the context of the related technology, and should not be interpreted in an ideal or excessively formal sense unless explicitly defined in the present application.

Hereinafter, a thermal processing apparatus, a thermal processing method, and substrate treatment equipment in which particle generation and damage to a substrate W in the cooling process of the substrate W can be prevented will be described. Thermal processing according to the present disclosure refers to the process of changing the properties of the substrate W by heating the substrate W. In the present disclosure, the thermal processing includes both heating and cooling processes on the substrate W. After the thermal processing on the substrate W is performed, the substrate W is required to be cooled for subsequent processing. The present disclosure is intended to prevent damage to the substrate and particles generation while rapidly cooling the substrate W.

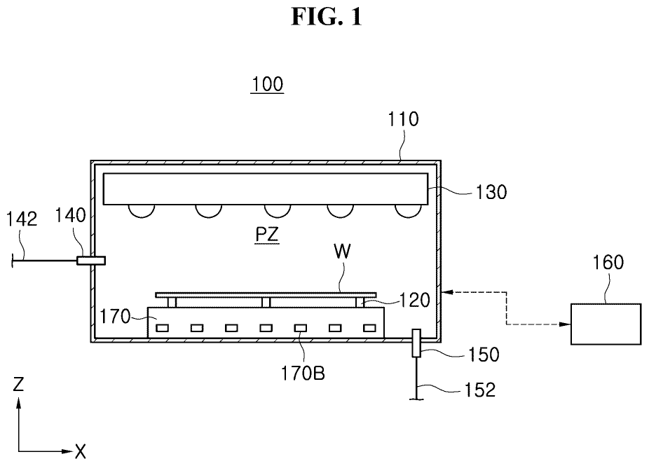

FIG. 1 schematically illustrates the structure of the thermal processing apparatus 100 according to the present disclosure. The thermal processing apparatus 100 according to the present disclosure may be provided as one module included in a semiconductor manufacturing equipment. After the thermal processing apparatus 100 heats and cools the substrate W, the thermal processing apparatus 100 may be discharged. In addition, the thermal processing apparatus 100 may further include an apparatus that performs process treatment (e.g., etching and deposition) on the substrate W, and the process treatment and thermal processing of the substrate W may be performed together.

The thermal processing apparatus 100 according to the present disclosure includes a chamber 110 having a processing zone PZ therein, a plurality of chuck pins 120 configured to support the substrate W at a back side thereof and move up or down individually, a heater 130 configured to provide heat energy to the processing zone PZ, a fluid supply port 140 configured to supply fluid to the processing zone PZ, a fluid discharge port 150 configured to discharge the fluid remaining in the processing zone PZ to the outside, and a controller 160 configured to control the process treatment of the substrate W. In addition, the thermal processing apparatus 100 may further include a cooling plate 170 having a cooling flow path through which coolant can flow.

The chamber 110 provides the processing zone PZ of the substrate W. The chamber 110 is configured to seal the processing zone PZ. A side wall of the chamber 110 is provided with an opening part through which the substrate W can pass, and a door to block or open the opening part. Various components for processing the substrate W are installed in the internal space of the chamber 110.

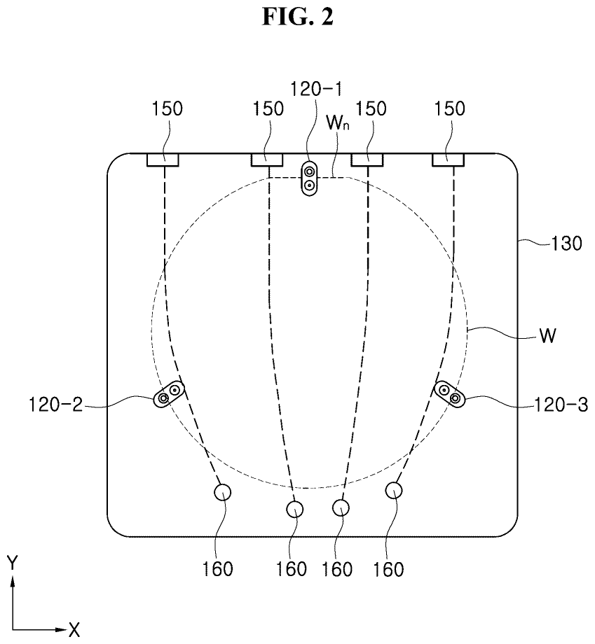

The chuck pin 120 supports the back surface and edge of the substrate W. The chuck pin 120 supports the substrate W at a back side thereof and prevents the substrate W from deviating from a correct position thereof. In order to ensure temperature uniformity, it is preferable that the chuck pin 120 includes the chuck pins of a minimum number to maintain the substrate W. In the embodiment of the present disclosure, the chuck pin 120 includes three chuck pins, wherein the three chuck pins may be arranged at equal intervals from each other. For example, as illustrated in FIG. 2, the chuck pin 120 includes three chuck pins 120-1, 120-2, and 120-3, and the three chuck pins 120-1, 120-2, and 120-3 may be arranged at equal intervals from each other. That is, as illustrated in FIG. 2, the chuck pins 120 may each be arranged at equal intervals with an angle of 120° therebetween. In the embodiment of the present disclosure, the chuck pin 120 may be made of quartz.

Meanwhile, referring to FIG. 2, a notch part Wn is formed on an area of a portion of the substrate W. The notch part Wn may be used as a marker to identify the direction of the substrate W. A driving device (e.g., a motor) may be provided on the lower part of the chuck pin 120 to raise or lower the chuck pin 120. In FIG. 2, the fluid supply port 140 is located on a first side of the chamber 110, and the fluid discharge port 150 is located on a second side thereof. In FIG. 2, one chuck pin 120-1 is located at a position adjacent to the fluid supply port 140, and two chuck pins 120-2 and 120-3 are respectively located at positions adjacent to the fluid discharge port 150. According to the present disclosure, a side of the substrate W directed to the fluid supply port 140 is maintained to be inclined downward, and a cooling fluid CF supplied to the substrate W flows in the form of pushing the substrate W upward and is then discharged through the fluid discharge port 150.

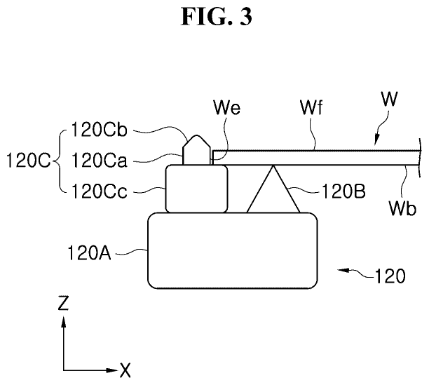

According to the embodiment of the present disclosure, the chuck pin 120 includes a body part 120A, an inner support part 120B located on the inner side of the upper surface of the body part 120A and configured to support the back surface Wb of the substrate W, and an outer support part 120C located on the outer side of the upper surface of the body part 120A and configured to support the edge side surface We of the substrate W. As illustrated in FIG. 3, the body part 120A is located at the edge of a position on which the substrate W is seated, and the inner support part 120B and the outer support part 120C are located on the body part 120A. The inner support part 120B and the outer support part 120C may be fixedly coupled to the body part 120A or may be formed integrally therewith.

The inner support part 120B has a triangular pyramid shape having a width decreasing upward. The upper end of the inner support part 120B having a triangular pyramid shape may be in contact with the back surface of the substrate W. That is, the inner support part 120B is in point contact with the back surface of the substrate W. Since the inner support part 120B is in point contact with the substrate W, the temperature change of the substrate W due to the chuck pin 120 may be minimized.

The outer support part 120C has a side wall 120Ca that is flat in a vertical direction Z and a head 120Cb extending from the side wall 120Ca and having a width decreasing gradually upward. The side wall 120Ca is in contact with the edge side surface We of the substrate W, and prevents the substrate W from deviating from a correction position thereof. The head 120Cb, which extends to the top of the side wall 120Ca, is provided to have a cone shape. By configuring the head 120Cb to have a width decreasing gradually upward, and by configuring the head 120Cb to become narrower toward the top, the substrate W may be stably supported on the chuck pin 120 despite a certain amount of error that occurs when the substrate W is loaded on the chuck pin 120. The outer support part 120C includes a base 120Cc that supports the back surface Wb at the edge of the substrate W. The side wall 120Ca and the head 120Cb are located on the base 120Cc.

The heater 130 provides heat energy for heating the substrate W. The heater 130 may be located at the upper part of the chamber 110 to supply heat energy downward. The heater 130 may be configured as an infrared (IR) lamp to focus heat on the substrate W.

The fluid supply port 140 can supply fluid for thermal processing of the substrate W. For example, the fluid supply port 140 may supply low-temperature fluid for cooling the substrate W. The fluid supply port 140 may supply fluid supplied from a fluid supply line 142 provided outside the chamber 110 to the internal space of the chamber 110. The fluid supply port 140 may be located on one side of the upper part of the chamber 110 and may supply fluid downward.

The fluid discharge port 150 may discharge the fluid remaining inside the chamber 110 to the outside. The fluid discharge port 150 may discharge the cooling fluid to the outside. The cooling fluid flowing into the fluid discharge port 150 may be discharged through a fluid discharge line 152 to the outside of the chamber 110. The fluid discharge port 150 may be located on one side of the lower part of the chamber 110. Negative pressure may be applied to the fluid discharge port 150 to discharge fluid.

As illustrated in FIG. 1, the fluid supply port 140 may be located the upper side of the chamber 110. In addition, the fluid discharge port 150 may be located on the lower side of the chamber 110 on the opposite side of the fluid supply port 140. A fluid supplied from the fluid supply port 140 to the processing zone PZ of the chamber 110 flows toward the fluid discharge port 150 located at the lower part of the chamber 110 at the opposite side of the fluid supply port 140, and accordingly, flows evenly along the upper surface Wf of the substrate W.

The controller 160 may control the operation of each component located inside the chamber 110 to process the substrate W. The controller 160 may consist of one or more processors (processing circuits). The controller 160 may control the operation of each component through electrical signals. The controller 160 may execute the thermal processing operation of the substrate W by executing instructions stored in memory. An instruction for the thermal processing operation of the substrate W may be received from a higher control system or input in advance. Particularly, the controller 160 may control operations for heating and cooling process of the substrate W.

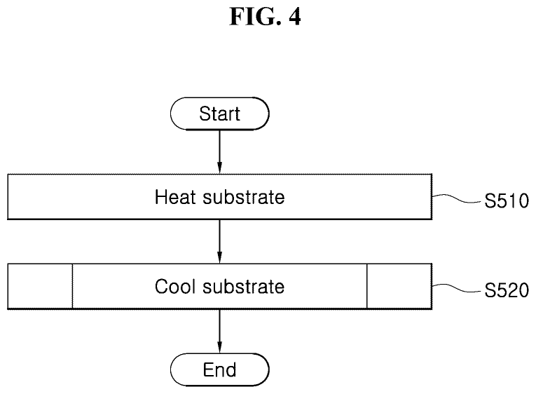

As illustrated in FIG. 4, the thermal processing method of the substrate W performed by the controller 160 according to the present disclosure includes heating the substrate W S410 by using the heater 130, and cooling the substrate W S420 when the heating of the substrate W is completed.

At S410, the heater 130 is activated in order to heat the substrate W. Heat energy emitted by the heater 130 is transferred to the substrate W, and the substrate W is heated by the heat energy. When the substrate W is heated at a target temperature (e.g., 200° C.) for a predetermined period of time (e.g., 120 seconds), the properties of materials formed on the substrate W may be changed.

At S420, when the heating the substrate W is completed, the process of cooling the substrate W is performed for rapid subsequent process. Particularly, the present disclosure is intended to prevent damage to the substrate W or particle generation due to temperature imbalance that occurs during cooling while rapidly cooling the substrate W.

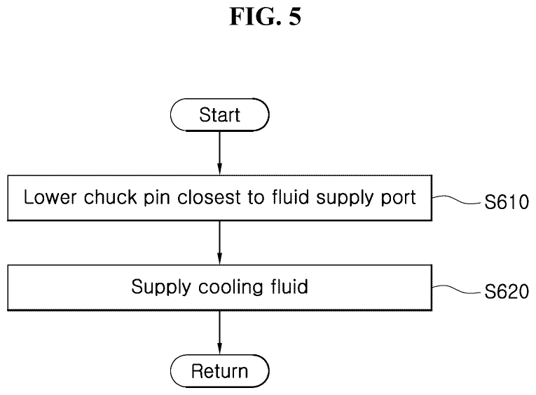

As illustrated in FIG. 5, the cooling of the substrate W at S420 includes controlling the height of the chuck pin 120 so that the substrate W is maintained to be inclined at S510, and supplying the cooling fluid CF through the fluid supply port 140 to the inclined substrate W at S520.

The controller 160 heats the substrate W by using the heater 130, when the heating of the substrate W stops, the height of the chuck pin 120 is controlled so that the substrate W is maintained to be inclined, and the cooling fluid is supplied through the fluid supply port 140 to the inclined substrate W.

At S510, the controller 160 may raise or lower each of the chuck pins 120 to maintain the substrate W to be inclined. The controller 160 may control each motor provided on the lower part of the chuck pin 120 to raise or lower each of the chuck pins 120.

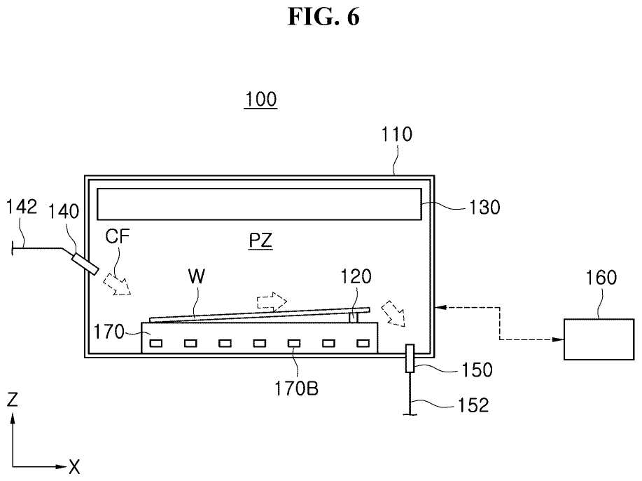

According to the embodiment of the present disclosure, the controlling of the height of the chuck pin 120 at S510 includes lowering the chuck pin 120-1 closest to the fluid supply port 140 among the plurality of chuck pins 120. The controller 160 may lower the chuck pin 120-1 closest to the fluid supply port 140 among the plurality of chuck pins 120. As illustrated in FIG. 6, the chuck pin 120-1 closest to the fluid supply port 140 may be lowered.

Except for the chuck pin 120-1 closest to the fluid supply port 140, the remaining two chuck pins 120-2 and 120-3 may be maintained without moving downward. For example, when the initial height of each of the chuck pins 120 is 1 cm, the chuck pin 120 closest to the fluid supply port 140 is lowered to the height of 0 cm and the remaining two chuck pins 120 may be maintained at the height of 1 cm.

According to the embodiment of the present disclosure, controlling the height of the chuck pin 120 at S510 includes identifying the position of the notch part Wn of the substrate W, and lowering the chuck pin 120-1 in non-contact with the notch part Wn of the substrate W and closest to the fluid supply port 140 among the plurality of chuck pins 120. The controller 160 identifies the position of the notch part Wn of the substrate W, and lowers the chuck pin 120-1 in non-contact with the notch part Wn of the substrate W and closest to the fluid discharge port 150 among the plurality of chuck pins 120.

When the chuck pin 120 is in contact with and supports the notch part Wn of the substrate W, the chuck pin 120 may not support the substrate W efficiently. When the chuck pin 120 in contact with the notch part Wn of the substrate W lowers, the substrate W may deviate from the chuck pin 120, and thus the chuck pin 120 in contact with the notch part Wn of the substrate W may be maintained so as not to lower. For example, as illustrated in FIG. 2, when the chuck pin 120-1 closest to the fluid supply port 140 is in contact with the notch part Wn of the substrate W, the chuck pin 120-1 does not lower and maintains an initial height thereof. In this case, when the other chuck pins 120-2 and 120-3 are raised to incline the substrate W, or the substrate W is horizontal without the controlling of the height of the chuck pin 120, the cooling fluid CF may be supplied to the substrate W. When the chuck pin 120-1 closest to the fluid supply port 140 is not in contact with the notch part Wn of the substrate W, the chuck pin 120-1 may be lowered to change the substrate W to be inclined. The position of the notch part Wn may be identified by a vision unit (e.g., a camera) located on the upper part of a transfer module of the substrate before the substrate W is loaded onto the chuck pin 120. In addition, according to the embodiment of the present disclosure, when the position of the notch part Wn of the substrate W is identified, the substrate W may be rotated and loaded on the chuck pin 120 so that the notch part Wn is not located on the chuck pin 120.

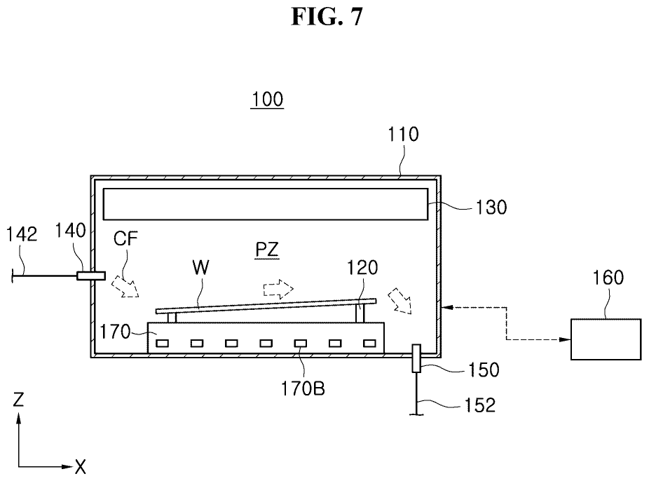

According to the embodiment of the present disclosure, the controlling of the height of the chuck pin 120 at S510 includes raising the chuck pins 120-2 and 120-3 closest to the fluid discharge port 150 among the plurality of chuck pins 120. The controller 160 may raise the chuck pins 120-2 and 120-3 closest to the fluid discharge port 150 among the plurality of chuck pins 120. For example, as illustrated in FIG. 7, the chuck pins 120-2 and 120-3 closest to the fluid discharge port 150 may be raised.

Except for the chuck pins 120-2 and 120-3 closest to the fluid discharge port 150, the remaining chuck pin 120-1 may be maintained without moving up. For example, when the initial height of each of the chuck pins 120 is 1 cm, the chuck pins 120-2 and 120-3 closest to the fluid discharge port 150 may rise to the height of 2 cm, and the remaining chuck pin 120-1 may be maintained at the height of 1 cm.

According to the embodiment of the present disclosure, the controlling of the height of the chuck pin at S510 includes identifying the position of the notch part Wn of the substrate W, and lowering a chuck pin in non-contact with the notch part Wn of the substrate W and closest to the fluid discharge port 150 among the plurality of chuck pins 120. The controller 160 identifies the position of the notch part Wn of the substrate W, and raising the chuck pins 120-2 and 120-3 in non-contact with the notch part Wn of the substrate W and closest to the fluid discharge port 150 among the plurality of chuck pins 120.

When the chuck pin 120 is in contact with and supports the notch part Wn of the substrate W, the chuck pin 120 may not support the substrate W efficiently. When the chuck pin 120 in contact with the notch part Wn of the substrate W is lowered, the substrate W may be deviate from the chuck pin 120, and thus the chuck pin 120 in contact with the notch part Wn of the substrate W may be maintained so as not to rise. For example, as illustrated in FIG. 2, when the chuck pin 120-1 closest to the fluid supply port 140 is in contact with the notch part Wn of the substrate W, the chuck pin 120-1 closest to the fluid supply port 140 may not be lowered and the chuck pins 120-2 and 120-3 closest to the fluid discharge port 150 may be raised so that the substrate W is maintained to be inclined. The position of the notch part Wn may be identified by the vision unit (e.g., a camera) located on the upper part of the transfer module of the substrate before the substrate W is loaded onto the chuck pin 120.

At S520, when the substrate W is maintained to be inclined, the cooling fluid CF is supplied thereto. The substrate W may be cooled more rapidly by the cooling fluid CF. According to the present disclosure, a side of the substrate W directed to the fluid supply port 140 is maintained to be inclined downward, and the cooling fluid CF supplied to the substrate W flows in the form of pushing the substrate W upward, and then is discharged through the fluid discharge port 150. It is checked that as in the present disclosure, by supplying the cooling fluid in the form of blowing the cooling fluid upward toward the inclined substrate W, the substrate W may be cooled rapidly and evenly, and thus damage to the substrate W and the generation of particles can be suppressed.

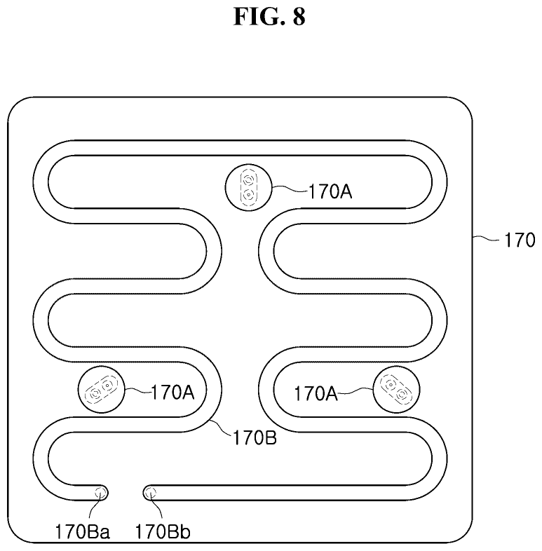

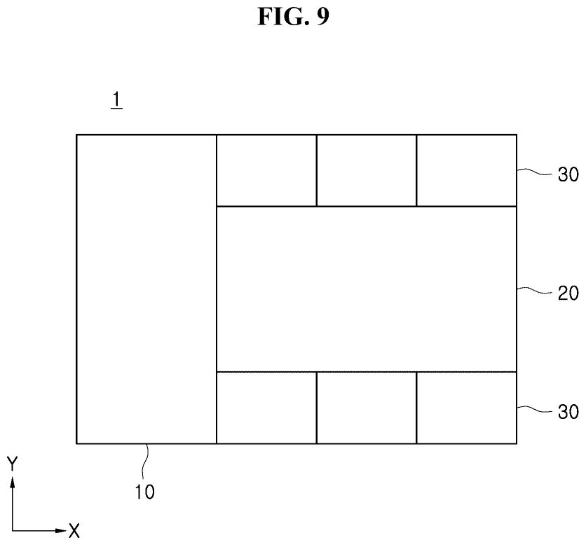

According to the embodiment of the present disclosure, the cooling plate 170 having a through hole 170A through which the chuck pin 120 can pass and the cooling flow path 170B in which a coolant can flow may be provided on the lower part of the chamber 110. Referring to FIGS. 1 and 8, the cooling plate 170 which is located under the substrate W and cools the substrate W is provided. The cooling plate 170 includes the through hole 170A through which the chuck pin 120 is formed to pass, and the cooling flow path 170B so that a coolant can pass therein. The cooling flow path 170B is formed in a maze shape so that the entire area of the substrate W can be cooled evenly, and an inlet 170Ba into which a coolant flows and an outlet 170Bb through which a coolant is discharged are respectively formed on the opposite ends of the cooling flow path 170B.

Meanwhile, the substrate treatment equipment 1 having a processing module 30 which is a mixture of the thermal processing apparatus according to the present disclosure and a plasma treatment device may be provided. In the substrate treatment equipment 1 according to the present disclosure, one processing module 30 may perform plasma treatment (e.g., etching and deposition) and thermal processing on the substrate W.

The substrate treatment equipment 1 according to the present disclosure includes a load port 10 configured to accommodate the container in which a plurality of substrates is stored, the processing module 30 configured to perform the process treatment on the substrate W, and the transfer module 20 configured to temporarily store the substrate W withdrawn from the container and transfer the substrate W to the processing module 30.

The load port 10 is arranged on one side of the substrate processing equipment 1 and provides a space in which the container (e.g., a front opening unified pod, FOUP) in which the substrate W is stored is seated. The load port 10 may open the door of the container to withdraw the substrate W, and transfer the withdrawn substrate W to the transfer module 20. In addition, the load port 10 may receive the substrate W whose treatment is completed from the transfer module 20, and store the substrate W in the container. The load port 10 may include a stage on which a plurality of containers are seated and an index robot that transfers the substrate W.

The transfer module 20 is arranged between the load port 10 and the processing module 30 and temporarily stores and transfers the substrate W. The transfer module 20 may include a load lock chamber that temporarily stores the substrate W, and a transfer robot that transfers the substrate into the processing module 30. Meanwhile, the load lock chamber of the transfer module 20 may be provided with a camera or sensor to identify the notch part Wn of the substrate W. The controller 160 may identify the location of the notch part Wn from the camera or sensor.

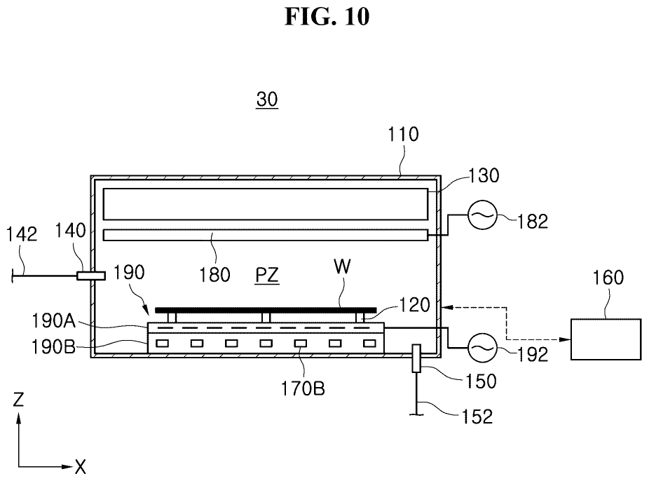

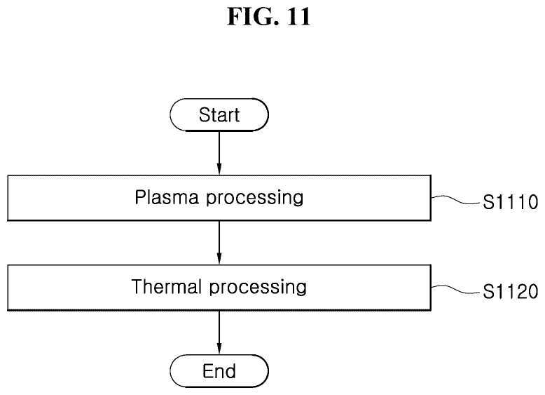

The processing module 30 performs process treatment on the substrate W. The processing module 30 may be configured as illustrated in FIG. 10, and perform plasma processing at 1110 and thermal processing at S1120 as illustrated in FIG. 11. The plasma processing at S1110 and the thermal processing at S1120 may be repeated a plurality of times.

In the embodiment of the present disclosure, the processing module 30 includes the chamber 110 having the processing zone PZ therein, the plurality of chuck pins 120 configured to support the substrate W and move up or down individually, an upper electrode 180 to which power is applied to generate plasma in the processing zone PZ, a chuck 190 located at the lower part of the processing zone PZ, with the chuck 190 having a lower electrode 190A for generating the plasma and a cooling plate 190B in which the cooling flow path 170B in which a coolant can flow is formed, the heater 130 configured to provide heat energy to the processing zone PZ, the fluid supply port 140 configured to supply a fluid to the processing zone PZ, the fluid discharge port 150 configured to discharge the fluid remaining in the processing zone PZ to the outside, and the controller 160 configured to control the process treatment of the substrate W.

The chamber 110, the chuck pin 120, the heater 130, the fluid supply port 140, the fluid discharge port 150, the controller 160 of FIG. 10 may be configured in the same way as those of the thermal processing apparatus 100 described by referring to FIG. 1. However, the fluid supply port 140 and the fluid discharge port 150 may supply and discharge treatment gas for plasma treatment as well as the cooling fluid CF. The upper electrode 180 and the lower electrode 190A use power provided from an upper RF power source 182 and a lower RF power source 192, respectively, to form an electromagnetic field inside the processing zone PZ. Plasma may be generated in the processing zone PZ by the electromagnetic field formed by the upper electrode 180 and the lower electrode 190A.

According to the embodiment of the present disclosure, the plasma processing at S1110 on the substrate W is performed, and after the plasma processing at S1110, the thermal processing at S1120 may be performed. In the thermal processing at S1120, heating and cooling of the substrate W may be performed.

According to the embodiment of the present disclosure, the controller 160 may supply power to the upper electrode 180 and the lower electrode 190A to perform plasma treatment on the substrate W, perform heating on the substrate W by using the heater 130, control the height of the chuck pin 120 so that the substrate W is maintained to be inclined when the heating is completed, and supply the cooling fluid through the fluid supply port to the inclined substrate W.

According to the present disclosure, the controller 160 may improve the cooling efficiency of the substrate W by controlling the height of the chuck pin 120 described through FIGS. 4 to 7. As illustrated in FIG. 6, the controller 160 may lower the chuck pin 120-1 closest to the fluid supply port 140 among the plurality of chuck pins 120. In addition, the controller 160 may identify the position of the notch part Wn of the substrate W, and may lower the chuck pin 120-1 in non-contact with the notch part Wn of the substrate W and closest to the fluid discharge port 150 among the plurality of chuck pins 120. As illustrated in FIG. 7, the controller 160 may raise the chuck pins 120-2 and 120-3 closest to the fluid discharge port 150 among the plurality of chuck pins 120. In addition, the controller 160 may identify the position the notch part Wn of the substrate W, and may raise the chuck pins 120-2 and 120-3 in non-contact with the notch part Wn of the substrate W and closest to the fluid discharge port 150 among the plurality of chuck pins 120.

This embodiment and the drawings attached to this specification only clearly show part of the technical idea included in the present disclosure, and it is self-evident that all modifications and specific embodiments that can be easily inferred by a person skilled in the art within the scope of the technical idea included in the specifications and drawings of the present disclosure are included in the scope of claims of the present disclosure.

Therefore, the idea of the present disclosure should not be limited to the described embodiments, and not only the scope of the claims described later, but also everything that is equivalent to the scope of the claims or is modified equivalently falls within the scope of the idea of the present disclosure.

What is claimed is:

1. A thermal processing apparatus comprising:
a chamber having a processing zone therein;
a plurality of chuck pins configured to support a substrate and move up or down individually;
a heater configured to provide heat energy to the processing zone;
a fluid supply port configured to supply a fluid to the processing zone;
a fluid discharge port configured to discharge the fluid remaining in the processing zone to outside; and
a controller configured to control a treatment process of the substrate,
wherein the controller is configured to:
heat the substrate by using the heater,
control a height of each of the chuck pins so that the substrate is maintained to be inclined, and
supply a cooling fluid through the fluid supply port to the inclined substrate.

2. The thermal processing apparatus of claim 1, wherein the plurality of chuck pins comprise three chuck pins, and the three chuck pins are arranged at equal intervals from each other.

3. The thermal processing apparatus of claim 1, wherein each of the plurality of chuck pins is made of quartz.

4. The thermal processing apparatus of claim 1, wherein each of the plurality of chuck pins comprises:
a body part;
an inner support part located on an inner side of an upper surface of the body part and configured to support a back surface of the substrate; and
an outer support part located on an outer side of the upper surface of the body part and configured to support an edge side surface of the substrate.

5. The thermal processing apparatus of claim 4, wherein the inner support part has a triangular pyramid shape having a width decreasing gradually upward.

6. The thermal processing apparatus of claim 4, wherein the outer support part has a side wall which is flat in a vertical direction and a head extending from the side wall and having a width decreasing gradually upward.

7. The thermal processing apparatus of claim 1, wherein the controller is configured to lower a chuck pin closest to the fluid supply port among the plurality of chuck pins.

8. The thermal processing apparatus of claim 1, wherein the controller is configured to:
identify a position of a notch part of the substrate; and
lower a chuck pin in non-contact with the notch part of the substrate and closest to the fluid supply port among the plurality of chuck pins.

9. The thermal processing apparatus of claim 1, wherein the controller is configured to raise a chuck pin closest to the fluid discharge port among the plurality of chuck pins.

10. The thermal processing apparatus of claim 1, wherein the controller is configured to:
identify a position of a notch part of the substrate; and
raise a chuck pin in non-contact with the notch part of the substrate and closest to the fluid discharge port among the plurality of chuck pins.

11. The thermal processing apparatus of claim 1, further comprising:
a cooling plate provided on a lower part of the chamber, and having a plurality of through holes through which the plurality of chuck pins pass and a cooling flow path in which a coolant flows.

12. The thermal processing apparatus of claim 1, wherein the fluid supply port is located on an upper side of the chamber.

13. The thermal processing apparatus of claim 12, wherein the fluid discharge port is located on a lower side of the chamber on an opposite side of the fluid supply port.

14. A thermal processing method performed by a thermal processing apparatus, wherein the thermal processing apparatus comprises:
a chamber having a processing zone therein;
a plurality of chuck pins configured to support a substrate and move up or down individually;
a heater configured to provide heat energy to the processing zone;
a fluid supply port configured to supply a fluid to the processing zone;
a fluid discharge port configured to discharge the fluid remaining in the processing zone to the outside; and
a controller configured to control a treatment process of the substrate, and
wherein the thermal processing method comprises:
heating the substrate by using the heater; and
cooling the substrate when the heating of the substrate is completed,
wherein the cooling of the substrate comprises:
controlling a height of each of the plurality of chuck pins so that the substrate is maintained to be inclined; and
supplying a cooling fluid through the fluid supply port to the inclined substrate.

15. The thermal processing method of claim 14, wherein the controlling of the height of each of the plurality of chuck pins comprises lowering a chuck pin closest to the fluid supply port among the plurality of chuck pins.

16. The thermal processing method of claim 14, wherein the controlling of the height of each of the plurality of chuck pins comprises:
identifying a position of a notch part of the substrate; and
lowering a chuck pin in non-contact with the notch part of the substrate and closest to the fluid supply port among the plurality of chuck pins.

17. The thermal processing method of claim 14, wherein the controlling of the height of each of the plurality of chuck pins comprises: raising a chuck pin closest to the fluid discharge port among the plurality of chuck pins.

18. The thermal processing method of claim 14, wherein the controlling of the height of each of the plurality of chuck pins comprises:
identifying a position of a notch part of the substrate; and
raising a chuck pin in non-contact with the notch part of the substrate and closest to the fluid discharge port among the plurality of chuck pins.

19. A substrate treatment equipment comprising:
a load port configured to accommodate a container in which a plurality of substrates is received;
a processing module configured to perform process treatment on each of the substrates; and
a transfer module configured to temporarily store the substrate withdrawn from the container and to transfer the substrate to the processing module,
wherein the processing module comprises:
a chamber having a processing zone therein;
a plurality of chuck pins configured to support the substrate and move up or down individually;
an upper electrode to which power is applied to generate plasma in the processing zone;
a chuck located at a lower part of the processing zone, with the chuck having a lower electrode for generating the plasma and a cooling plate in which a cooling flow path in which a coolant is capable of flowing is formed;
a heater configured to provide heat energy to the processing zone;
a fluid supply port configured to supply a fluid to the processing zone;
a fluid discharge port configured to discharge the fluid remaining in the processing zone to the outside; and
a controller configured to control the process treatment of the substrate,
wherein the controller is configured to:
supply power to the upper electrode and the lower electrode to perform plasma processing on the substrate,
perform thermal processing on the substrate by using the heater,
control a height of each of the plurality of chuck pins so that the substrate is maintained to be inclined, and
supply a cooling fluid through the fluid supply port to the inclined substrate.

20. The substrate treatment equipment of claim 19, wherein the controller is configured to:
identify a position of a notch part of a first substrate of the plurality of substrates; and
lower a first chuck pin, among the plurality of chuck pins, in non-contact with the notch part of the first substrate and closest to the fluid supply port.
